(19) United States
(12) Patent Application Publication
(10) Pub. No.: US 2023/0129597 A1
(43) Pub. Date: Apr. 27, 2023

(54) Retaining Ring for Wafer Polishing

(71) Applicant: SCH POWER TECH CO., LTD., Hsinchu County (TW)

(72) Inventors: Ho-Hsi Yeh, Hsinchu County (TW); Wen-Pin Chen, Hsinchu County (TW)

(21) Appl. No.: 17/511,730

(22) Filed: Oct. 27, 2021

(51) Int. Cl. H01L 21/687; B24B 37/32

(52) U.S. Cl. CPC H01L 21/68721; B24B 37/32

(57) ABSTRACT

A retaining ring is provided by fitting several parts. The parts comprises a fixing ring, a grinding ring, and an adhesive part. The fixing ring has a first fixing part, a second fixing part, and an abutting surface. The grinding ring has a first retaining part, a second retaining part, and a corresponding abutting surface. After assembling the first retaining part and first fixing part and assembling the second retaining part and second fixing part, a gap is separately formed between the first retaining part and first fixing part and between the second retaining part and second fixing part. When the adhesive part is adhered between the abutting surface and corresponding abutting surface, the gaps are tightly closed. Thus, the fixing ring and grinding ring are easy to be assembled and solidly combined, and obtain reinforced structural strength.

### TECHNICAL FIELD OF THE INVENTION

The present invention relates to a retaining ring; more particularly, to proving a fixing ring and a grinding ring, which are easy to be assembled and solidly bonded, and obtain reinforced structural strength.

### DESCRIPTION OF THE RELATED ARTS

Generally, the retaining ring of a semiconductor wafer is formed by combining two different materials of metal and non-metal, or two rings of both non-metal. The metal and non-metal bodies of the retaining ring are usually assembled by embedding or adhering.

Due to the level difference formed during fitting the retaining ring, there will be a gap in the overlapped part of the two fitted parts. On pressing a polishing pad, there will be a great amount of strain formed at the gap of the second ring, which may affect the flatness and uniformity. Furthermore, dovetail fitting requires very precise center alignment and a lot of down force for combination. If the center alignment is incorrect, there may be a risk of internal fracture hard to find.

Because of the horizontal rotation and movement, the wafer retaining ring will bear torsion and lateral force on combining, where the grinding ring may be easily peeled off. Hence, the prior art does not fulfill all users' requests on actual use.

### SUMMARY OF THE INVENTION

The main purpose of the present invention is to provide a fixing ring and a grinding ring, which are easy to be assembled and solidly bonded, and obtain reinforced structural strength.

To achieve the above purpose, the present invention is a retaining ring for wafer polishing, comprising a fixing ring, a grinding ring, and an adhesive part, where, on a surface, the fixing ring comprises a first fixing part, a second fixing part, an abutting surface, and a plurality of air vents; the first fixing part and the second fixing part are set adjacently; the abutting surface is set between the first fixing part and the second fixing part; and each of the air vents is respectively set between the first fixing part and the second fixing part and respectively connects to the abutting surface and an opposite surface of the fixing ring; the grinding ring is combined with the fixing ring; the grinding ring and the fixing ring are of different materials; on a surface, the grinding ring has a plurality of draining channels; on an opposite surface, the grinding ring comprises a first retaining part, a second retaining part, and a corresponding abutting surface; the first retaining part and the second retaining part are set adjacently; the corresponding abutting surface is set between the first retaining part and the second retaining part; the first retaining part and the first fixing part are assembled together; the second retaining part and the second fixing part are assembled together; the abutting surface and the corresponding abutting surface abut against each other; the adhesive part is set between the abutting surface and the corresponding abutting surface; the first fixing part is larger than the first retaining part; the second fixing part is larger than the second retaining part; after assembling the first retaining part and the first fixing part and assembling the second retaining part and the second fixing part, a gap is separately formed between the first retaining part and the first fixing part and between the second retaining part and the second fixing part; and, after adhering the adhesive part between the abutting surface and the corresponding abutting surface, the first retaining part and the second retaining part move toward the same side by thermal expansion and contraction to make the gap tightly closed to combine the grinding ring and the fixing ring. Accordingly, a novel retaining ring for wafer polishing is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the perspective view showing the preferred embodiment according to the present invention;

FIG. 2 is the disassembled view;

FIG. 3 is the first sectional view;

FIG. 4 is the second sectional view; and

FIG. 5 is the third sectional view.

### DESCRIPTION OF THE PREFERRED EMBODIMENT

The following description of the preferred embodiment is provided to understand the features and the structures of the present invention.

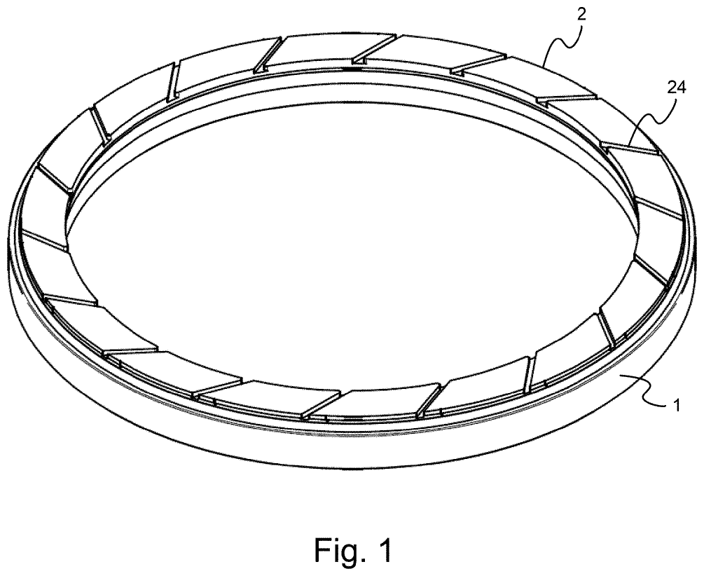

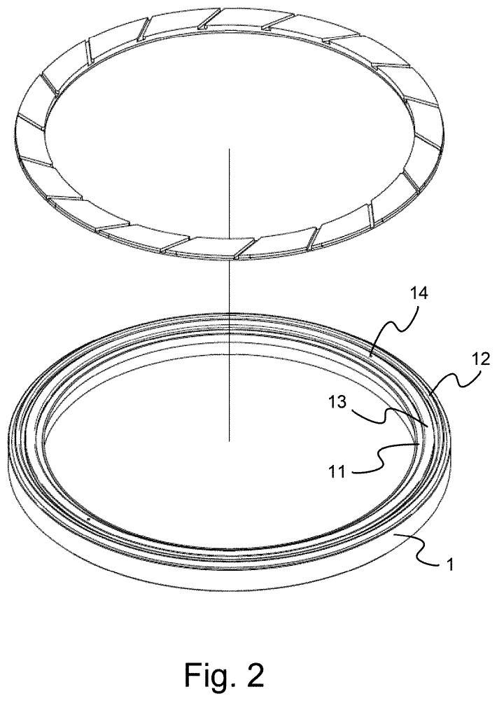

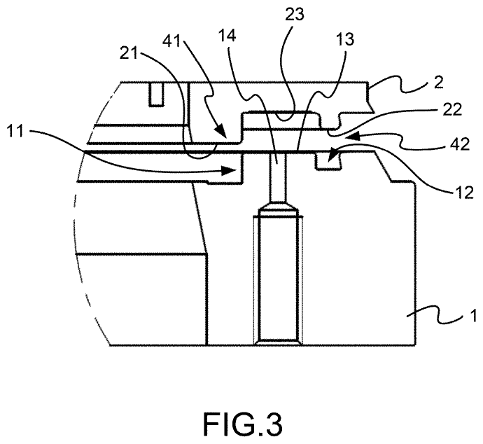

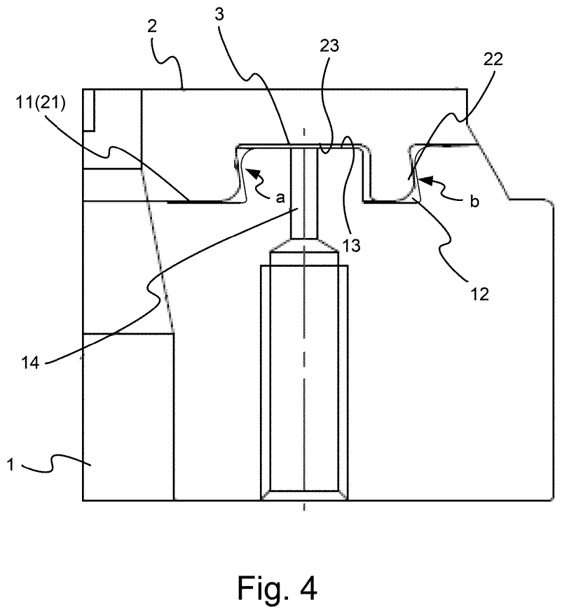

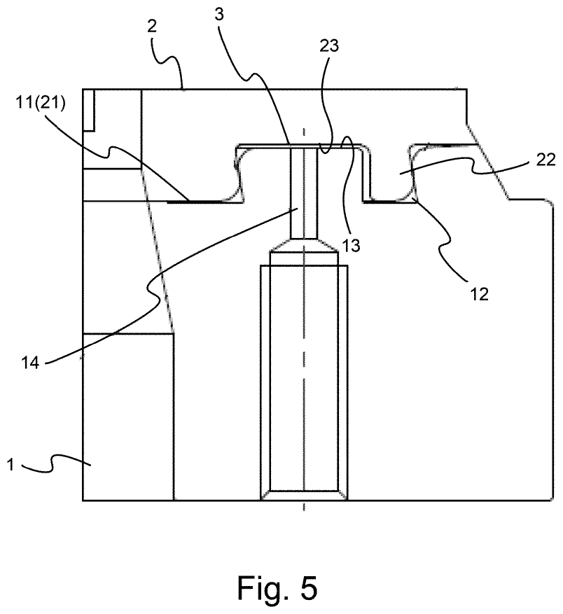

Please refer to FIG. 1 to FIG. 5, which are a perspective view showing a preferred embodiment according to the present invention; a disassembled view; a first sectional view; a second sectional view; and a third sectional view. As shown in the figures, the present invention is a retaining ring for wafer polishing, comprising a fixing ring 1, a grinding ring 2, and an adhesive part 3.

On a surface, the fixing ring 1 comprises a first fixing part 11, a second fixing part 12, an abutting surface 13, and a plurality of air vents 14. The first fixing part 11 and the second fixing part 12 are set adjacently. The abutting surface 13 is set between the first fixing part 11 and the second fixing part 12. Each of the air vents 14 is respectively set between the first fixing part 11 and the second fixing part 12 and respectively connects to the abutting surface 13 and an opposite surface of the fixing ring 1.

The grinding ring 2 is combined with the fixing ring 1. The grinding ring 2 and the fixing ring 1 are of different materials. On a surface, the grinding ring 2 has a plurality of draining channels; and, on an opposite surface, the grinding ring 2 comprises a first retaining part 21, a second retaining part 22, and a corresponding abutting surface 23. The first retaining part 21 and the second retaining part 22 are set adjacently. The corresponding abutting surface 23 is set between the first retaining part 21 and the second retaining part 22. The first retaining part 21 and the first fixing part 11 are assembled together; the second retaining part 22 and the second fixing part 12 are assembled together; and the corresponding abutting surface 23 and the abutting surface 13 abut against each other.

The adhesive part 3 is set between the abutting surface 13 and the corresponding abutting surface 23.

Therein, the first fixing part 11 is larger than the first retaining part 21; and the second fixing part 12 is larger than the second retaining part 22.

On combining the fixing ring 1 and the grinding ring 2, the adhesive part 3 is coated on the abutting surface 13 or the corresponding abutting surface 23 before assembling. Then, the first retaining part 21 and the second retaining part 22 are respectively combined with the first fixing part 11 and the second fixing part 12. After assembling the first retaining part 21 and the first fixing part 11 and assembling the second retaining part 22 and the second fixing part 12, a gap 41,42 is separately formed between the first retaining part 21 and the first fixing part 11 and between the second retaining part 22 and the second fixing part 12. After adhering the adhesive part 3 between the abutting surface 13 and the corresponding abutting surface 23, the first retaining part 21 and the second retaining part 22 move toward the same side by thermal expansion and contraction to make the gap 41,42 tightly closed for combining the grinding ring 2 and the fixing ring 1.

Moreover, as the grinding ring 2 and the fixing ring 1 are combined, air between the grinding ring 2 and the fixing ring 1 is exhaust with the coordination of the air vents 14 for avoiding uneven adhesion of the adhesive part 3 or the generation of air bubbles. At a place combining the first fixing part 11 and the first retaining part 21 or combining the second fixing part 12 and the second retaining part 22, a tapered structure is formed at at least one place for increasing the stability after combining the grinding ring 2 and the fixing ring 1.

Furthermore, the fixing ring 1 can be heated before the combination where the temperature of the fixing ring 1 is increased by more than 60 degrees Celsius (° C.). Then, the first retaining part 21 and the second retaining part 22 are respectively combined with the first fixing part 11 and the second fixing part 12. As the gap 41,42 in between become larger after being heated, the grinding ring 2 is easily combined with the fixing ring 1. When the fixing ring 1 is cooled down to a room temperature, the gap 41,42 is tightly closed to combine the grinding ring 2 and the fixing ring 1.

Thus, the fixing ring 1 and the grinding ring 2 do not need to be too precisely center-aligned. There is not much interference between the fixing ring 1 and the grinding ring 2 during assembly. Furthermore, there is no risk of breakage when the grinding ring 2 is pressed down for the combination. Hence, the fixing ring 1 and the grinding ring 2 are easy to be assembled and solidly combined, and obtain reinforced structural strength.

In a state-of-use, the fixing ring 1 is made of a metal material with better rigidity. Therewith, the fixing ring 1 obtains better supporting force for preventing the grinding ring 2 from deformation.

In a state-of-use, the grinding ring 2 is a non-metallic material with high wear resistance and chemical corrosion resistance. Therewith, the wafer is avoided from scratching during grinding with the service life of the grinding ring 2 extended.

In a state-of-use, the first fixing part 11 is concave; the first retaining part 21 is convex; and the gap 41 is thus formed after combining the first fixing part 11 and the first retaining part 21.

In a state-of-use, the second fixing part 12 is concave; the second retaining part 22 is convex; and the gap 42 is thus formed after combining the second fixing part 21 and said second retaining part 22.

Accordingly, after assembling the first retaining part 21 and the first fixing part 11 and assembling the second retaining part 22 and the second fixing part 12, the gap 41,42 is separately formed between the first retaining part 21 and the first fixing part 11 and between the second retaining part 22 and the second fixing part 12. After adhering the adhesive part 3 between the abutting surface 13 and the corresponding abutting surface 23, the first retaining part 21 and the second retaining part 22 move toward the same side by thermal expansion and contraction to make the gap 41,42 tightly closed for combining the grinding ring 2 and the fixing ring 1.

In a state-of-use, the draining channels 24 are set obliquely; and each of the draining channels has an inclining angle between 35 degrees (°) and 45° as 40° is preferred. In this way, when the grinding ring 2 grinds wafer, the draining channels 24 easily drain the working fluid and waste particles with the inclining angle.

In a state-of-use, the adhesive part 3 is made of epoxy resin. Therewith, after adhering the adhesive part 3 between the abutting surface 13 and the corresponding abutting surface 23, the first retaining part 21 and the second retaining part 22 move toward the same side by thermal expansion and contraction to make the gap 41,42 tightly closed for combining the grinding ring 2 and the fixing ring 1. With the grinding ring 2 combined with the fixing ring 1, air between the grinding ring 2 and the fixing ring 1 is exhaust with the coordination of the air vents 14 for avoiding uneven adhesion of the adhesive part 3 or the generation of air bubbles.

To sum up, the present invention is a retaining ring for wafer polishing, where a fixing ring and a grinding ring are easy to be assembled and solidly bonded, and obtain reinforced structural strength.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

1. A retaining ring for wafer polishing comprising:
a fixing ring comprising a first fixing part, a second fixing part, an abutment surface disposed between said first fixing part and said second fixing part, and a plurality of air vents; each of said air vents is respectively disposed between said first fixing part and said second fixing part and respectively extends between the abutment surface and an opposite surface of said fixing ring;
a grinding ring combined with said fixing ring; said grinding ring and said fixing ring are of different materials; on a surface, said grinding ring has a plurality of draining channels disposed obliquely; on an opposite surface, said grinding ring comprises a first retaining part, a second retaining part, and a corresponding grinding ring abutment surface disposed between said first retaining part and said second retaining part; said first retaining part and said first fixing part are assembled together; said second retaining part and said second fixing part are assembled together; and said fixing ring abutment surface and said corresponding grinding ring abutment surface engage each other; and
an adhesive part between said fixing ring abutment surface and said corresponding grinding ring abutment surface, wherein said first fixing part is larger than said first retaining part; said second fixing part is larger than said second retaining part; and a single surface of the first and of the second fixing parts and a corresponding single surface of the first and of the second retaining parts is tapered; after assembling said first retaining part and said first fixing part and assembling said second retaining part and said second fixing part, a first gap is separately formed between said first retaining part and said first fixing part and a second gap is separately formed between said second retaining part and said second fixing part; and, after adhering said adhesive part between said fixing ring abutment surface and said corresponding grinding ring abutment surface, said first retaining part and said second retaining part move by thermal expansion to make said first and second gaps close to combine said grinding ring and said fixing ring.

2. The retaining ring according to claim 1, wherein said first fixing part is concave; said first retaining part is convex; and said first gap is obtained after combining said first fixing part and said first retaining part.

3. The retaining ring according to claim 1, wherein said second fixing part is concave; said second retaining part is convex; and said second gap is obtained after combining said second fixing part and said second retaining part.

4. The retaining ring according to claim 1, wherein said fixing ring is made of a metal material.

5. The retaining ring according to claim 1, wherein said grinding ring is a non-metallic material.

6. The retaining ring according to claim 1, wherein each of said draining channels has an inclining angle between 35 degrees (°) and 45°.

7. The retaining ring according to claim 1, wherein said adhesive part is made of epoxy resin.
